(19) United States
(12) Patent Application Publication
(10) Pub. No.: US 2025/0066905 A1
(43) Pub. Date: Feb. 27, 2025

(54) METHODS AND SYSTEMS FOR FILLING A GAP

(71) Applicant: ASM IP Holding B.V., Almere (NL)

(72) Inventors: René Henricus Jozef Vervuurt, Leuven (BE); Timothee Blanquart, Oud-Heverlee (BE); Charles Dezelah, Helsinki (FI)

(21) Appl. No.: 18/811,842

(22) Filed: Aug. 22, 2024

Related U.S. Application Data
(60) Provisional application No. 63/534,670, filed on Aug. 25, 2023.

(51) Int. Cl. C23C 16/04; C23C 16/12; C23C 16/455; C23C 16/52; C23C 16/56

(52) U.S. Cl. CPC C23C 16/045; C23C 16/12; C23C 16/45514; C23C 16/52; C23C 16/56

(57) ABSTRACT

Disclosed are methods and systems for filling a gap. A method comprises providing a substrate to a reaction chamber. The substrate comprises the gap. The method further comprises at least partially filling the gap with a gap filling fluid. The method then comprises subjecting the gap filling fluid to a transformation treatment, thus forming a transformed material in the gap. The methods and systems are useful, for example, in the field of integrated circuit manufacture.

### CROSS-REFERENCE TO RELATED APPLICATIONS

This application claims priority to and the benefit of U.S. Provisional Application No. 63/534,670, filed Aug. 25, 2023, the entirety of which is incorporated by reference herein.

### FIELD OF INVENTION

The present disclosure generally relates to the field of semiconductor processing methods and systems, and to the field of integrated circuit manufacture. In particular, methods and systems for filling a gap are disclosed.

### BACKGROUND OF THE DISCLOSURE

The scaling of semiconductor devices, such as, for example, logic devices and memory devices, has led to significant improvements in speed and density of integrated circuits. However, conventional device scaling techniques face significant challenges for future technology nodes.

For example, one challenge has been finding suitable ways of filling gaps, such as recesses, trenches, vias and the like with a material without formation of any gaps or voids.

Any discussion, including discussion of problems and solutions, set forth in this section has been included in this disclosure solely for the purpose of providing a context for the present disclosure. Such discussion should not be taken as an admission that any or all of the information was known at the time the invention was made or otherwise constitutes prior art.

### SUMMARY OF THE DISCLOSURE

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

Various embodiments of the present disclosure relate to methods of filling a gap, to structures and devices formed using such methods, and to apparatus for performing the methods and/or for forming the structures and/or devices.

Thus described herein is a method for filling a gap. The method comprises providing a substrate comprising a gap to a reaction chamber. Then, providing a metal precursor into the reaction chamber in vapor phase and providing a halogen precursor into the reaction chamber in vapor phase, thereby forming a gap filling fluid. The gap filling fluid is exposed to a transformation reactant, thereby converting at least part of the gap filling fluid into a transformed material.

In some embodiments, the method for filling the gap further comprises executing a plurality of super cycles, a super cycle comprising at least partially filling the gap with a gap filling fluid, and the step of subjecting the substrate to a transformation reactant.

Further described herein is a method for filling a gap. The method comprises providing a substrate comprising a gap, providing a system comprising a gap filling fluid reaction chamber and a transformation reaction chamber, and executing a plurality of super cycles. A super cycle comprises moving the substrate into the gap filling fluid reaction chamber and forming a gap filling fluid in the gap filling fluid reaction chamber, thereby at least partially filling the gap with the gap filling fluid.

In some embodiments, the metal precursor comprises a metal and a hydrocarbon ligand.

In some embodiments, the metal precursor comprises an element selected from the group consisting of W, Ge, Sb, Te, Nb, Ta, V, Ti, Zr, Rh, Fe, Cr, Mo, Au, Pt, Ag, Ni, Cu, Co, Zn, Al, In, Sn, and Bi.

In some embodiments, the metal precursor comprises an element selected from the group consisting of V, Mo, Ti and Al.

In some embodiments, the metal precursor comprises Al.

In some embodiments, the hydrocarbon ligand in the metal precursor comprises an alkyl group or an alkoxide group.

In some embodiments, the halogen precursor comprises a halogen.

In some embodiments, the halogen precursor is selected from the group consisting of halohydrocarbons, dihalogens, hydrogen halides, ammonium halides, and halosilanes.

In some embodiments, the gap filling fluid comprises a metal halide.

In some embodiments, the transformation reactant comprises an oxidizing reactant.

In some embodiments, the oxidizing reactant is selected from the group consisting of ozone, water, steam, vacuum ultraviolet ozone and oxygen plasma.

Further described herein is a system that comprises a reaction chamber. The system further comprises a first precursor gas source that in turn comprises a metal precursor. The system further comprises a second precursor gas source that in turn comprises a halogen precursor. The system further comprises a controller. The controller is configured to control gas flow into the reaction chamber to carry out a method as described herein.

These and other embodiments will become readily apparent to those skilled in the art from the following detailed description of certain embodiments having reference to the attached figures. The invention is not limited to any particular embodiments disclosed.

### BRIEF DESCRIPTION OF THE DRAWING FIGURES

A more complete understanding of the embodiments of the present disclosure may be derived by referring to the detailed description and claims when considered in connection with the following illustrative figures.

FIG. 1 illustrates an embodiment of a method as disclosed herein.

FIG. 2 illustrates an embodiment of a system (200) in accordance with yet additional exemplary embodiments of the disclosure.

FIG. 3 shows another embodiment of a system (300) as described herein in a stylized way.

FIG. 4 shows a stylized representation of a substrate (400) comprising a gap (410).

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below.

In this disclosure, “gas” can include material that is a gas at normal temperature and pressure (NTP), a vaporized solid and/or a vaporized liquid, and can be constituted by a single gas or a mixture of gases, depending on the context. A gas other than the process gas, i.e., a gas introduced without passing through a gas distribution assembly, other gas distribution device, or the like, can be used for, e.g., sealing the reaction space, and can include a seal gas, such as a rare gas. In some cases, the term “precursor” can refer to a compound that participates in the chemical reaction that produces another compound, and particularly to a compound that constitutes a film matrix or a main skeleton of a film; the term “reactant” can be used interchangeably with the term precursor.

As used herein, the term “film” and/or “layer” can refer to any continuous or non-continuous structure and material, such as material deposited by the methods disclosed herein. For example, a film and/or layer can include two-dimensional materials, three-dimensional materials, nanoparticles, partial or full molecular layers or partial or full atomic layers or clusters of atoms and/or molecules. A film or layer may partially or wholly consist of a plurality of dispersed atoms on a surface of a substrate and/or embedded in a substrate/and/or embedded in a device manufactured on that substrate. A film or layer may comprise material or a layer with pinholes and/or isolated islands. A film or layer may be at least partially continuous. A film or layer may be patterned, e.g. subdivided, and may be comprised in a plurality of semiconductor devices.

As used herein, a “structure” can be or can include a substrate as described herein. Structures can include one or more layers overlying the substrate, such as one or more layers formed according to a method as described herein. Device portions can be or include structures. A transformed material manufactured by means of a method as described herein can be or can become a part of a structure.

As used herein, the term “gap filling fluid”, also referred to as “flowable gap fill”, may refer to a composition of matter that is liquid, or that can form a liquid, under the conditions under which is formed and which has the capability to form a solid film. A gap filling fluid can be in a flowable state permanently, or at least temporarily, i.e., for a pre-determined amount of time before the gap filling fluid solidifies. It shall be understood that the gap filling fluid used in, or formed during, a method as described herein comprises at least one of a metal and a metalloid. In some embodiments, the gap filling fluid further comprises a halogen. Alternatively, and in some embodiments, the gap filling fluid does not comprise a halogen. It shall be understood that “gap filling fluid” can, in some embodiments, be only temporarily in a flowable state, for example when the “gap filling fluid” is temporarily formed through formation of liquid oligomers from gaseous monomers during a polymerization reaction, and the liquid oligomers continue to polymerize to form a solid polymeric material. For ease of reference, a solid material formed from a gap filling fluid may, in some embodiments, be simply referred to as “gap filling fluid”.

In some embodiments, the gap filling fluid comprises a compound in a liquid phase that undergoes a gelification process.

In some embodiments, the gap filling fluid comprises oligomers that undergo chain growth as gaseous precursor polymerizes. Accordingly, a flowable oligomer-containing gap filling fluid can, in some embodiments, be temporarily formed on the substrate's surface that solidifies as the oligomers undergo chain growth. Thus, a flowable gap filling fluid can be obtained even at temperatures that are lower than the bulk melting point of a converted layer that is formed by a method as disclosed herein.

Of course, the presently described methods can also be used at conversion temperatures which exceed the bulk melting point of gap filling fluids formed by the presently described methods.

In some embodiments, a gap filling fluid can be formed even at process conditions at which a bulk gap filling fluid would be normally not be expected to exist in a liquid state, e.g., at temperatures above the bulk gap filling fluid's dew point, or at pressures below the bulk gap filling fluid's critical pressure. In such cases, a gap filling fluid can be formed in gaps through surface tension and capillary effects that locally lower the vapor pressure at which liquid and gas are in equilibrium. In such cases, the gap filling fluid can, in some embodiments, be solidified by cooling the substrate down.

A gap filling fluid can be formed over the entire substrate surface, both outside gaps and inside gaps comprised in the substrate. When the gap filling fluid is formed both outside of the gaps and inside the gaps, the gap filling fluid can, in some exemplary modes of operation, be drawn into a gap by at least one of capillary forces, surface tension, and gravity.

A method as described herein can comprise forming a material such as a gap filling fluid by means of a cyclic deposition process. The term “cyclic deposition process” or “cyclical deposition process” can refer to a sequential introduction of precursors (and/or reactants) into a reaction chamber to deposit a layer over a substrate. A cyclical deposition process can include cyclically providing a precursor, providing a reactant, and generating a plasma in a reaction chamber. Additionally or alternatively, a cyclical deposition process can include cyclically exposing a substrate to active species generated in a remote plasma.

As used herein, the term “purge” may refer to a procedure in which at least one of flow of a precursor, flow of a reactant, and exposure of a substrate to active species, is temporarily stopped. Suitably, active species can be generated by means of a plasma, for example during formation of a gap filling fluid. A purge can occur between two pulses. A pulse can comprise executing a process step such as exposing a substrate to one or more of precursor, providing reactant, and optionally plasma, for a pre-determined amount of time. A purge then comprises temporarily stopping exposure of the substrate to one or more of precursor, reactant, and optionally plasma. It shall be understood that a purge can be effected either in time or in space, or both. For example, in the case of temporal purges, a purge step can be used, e.g., in the temporal sequence of providing a first precursor to a reaction chamber, providing a purge gas to the reaction chamber, and providing a second precursor to the reaction chamber, wherein the substrate on which a layer is deposited does not move. For example, in the case of spatial purges, a purge step can take the following form: moving a substrate from a first location to which a first precursor is continually supplied, through a purge gas curtain, to a second location to which a second precursor is continually supplied.

As used herein, a “precursor” includes a gas or a material that can become gaseous and that can be represented by a chemical formula that includes an element that may be incorporated in a gap filling fluid or a transformed material during a process as described herein. The terms “precursor” and “reactant” can be used interchangeably, in some embodiments. Alternatively, a reactant can comprise a gaseous species, e.g., a noble gas, that interacts with a precursor without becoming incorporated in a gap filling fluid or a transformed material.

Further, in this disclosure, any two numbers of a variable can constitute a workable range of the variable, and any ranges indicated may include or exclude the endpoints. Additionally, any values of variables indicated may refer to precise values or approximate values and include equivalents, and may refer to average, median, representative, majority, or the like. Further, in this disclosure, the terms “including,” “constituted by” and “having” refer independently to “typically or broadly comprising,” “comprising,” “consisting essentially of,” or “consisting of” in some embodiments.

“At least one”, “one or more”, and “and/or” are open-ended expressions that are both conjunctive and disjunctive in operation. For example, each of the expressions “at least one of A, B, and C”, “at least one of A, B, or C”, “one or more of A, B, and C”, “one or more of A, B, or C” and “A, B, and/or C” means A alone, B alone, C alone, A and B together, A and C together, B and C together, or A, B and C together. When each one of A, B, and C in the above expressions refers to an element, such as X, Y, and Z, or class of elements, such as X₁-Xₙ, Y₁-Yₘ, and Z₁-Zₒ, the phrase is intended to refer to a single element selected from X, Y, and Z, a combination of elements selected from the same class (e.g., X₁ and X₂), as well as a combination of elements selected from two or more classes (e.g., Y₁ and Zₒ).

It shall be understood that a distal portion of a gap refers to a portion of the gap feature that is relatively far removed from a substrate's surface, and that the proximal portion of a gap feature refers to a part of the gap feature that is closer to the substrate's surface compared to the lower/deeper portion of the gap feature.

In this disclosure, any defined meanings do not necessarily exclude ordinary and customary meanings, in some embodiments.

The materials formed according to the present methods can be advantageously used in the field of integrated circuit manufacture.

As used herein, the term “substrate” may refer to any underlying material or materials, including any underlying material or materials that may be modified, or upon which, a device, a circuit, or a film may be formed. The “substrate” may be continuous or non-continuous; rigid or flexible; solid or porous; and combinations thereof. Substrates may be made from semiconductor materials, including, for example, silicon, silicon germanium, silicon oxide, gallium arsenide, gallium nitride, and/or silicon carbide.

A continuous substrate may extend beyond the bounds of a process chamber where a deposition process occurs. In some processes, the continuous substrate may move through the process chamber such that the process continues until the end of the substrate is reached. A continuous substrate may be supplied from a continuous substrate feeding system to allow for manufacture and output of the continuous substrate in any appropriate form.

Described herein is a method for filling a gap. The method comprises providing a substrate comprising a gap to a reaction chamber. The method further comprises providing a metal precursor into the reaction chamber in vapor phase and providing a halogen precursor into the reaction chamber in vapor phase, thereby forming a gap filling fluid. In some embodiments, the substrate comprises a plurality of gaps, e.g., from at least 10 gaps to at most 1012 gaps; one or more of which, for example, all of which, may be at least partially filled with a gap filling fluid. The method further comprises exposing the gap filling fluid to a transformation reactant, thereby converting at least part of the gap filling fluid into a transformed material. Suitable transformed materials include metal oxides.

It shall be understood that converting the gap filling fluid at least partially into a transformed material comprises a thermal process. A thermal process comprises subjecting a substrate to heat energy, without subjecting the substrate to a plasma or active species such as radicals. Thermal processes as such are known in the art, and include soak anneals, rapid thermal anneals, microwave anneals, and the like. A thermal process can comprise exposing the substrate to a suitable ambient, such as an ambient containing oxygen, or an ambient containing nitrogen, or an ambient containing carbon, or an ambient containing hydrogen, or an ambient containing a noble gas.

In some embodiments, the conversion step comprises exposing the gap filling fluid to an oxidizing reactant. The purpose of the oxidizing agent is to convert the metal-containing gap filling fluid to a metal oxide. Any suitable oxidizing reactant can be used. In some embodiments, the oxidizing reactant is one or more of ozone, steam, vacuum ultraviolet (VUV)-ozone or water.

In some embodiments, the conversion step comprises exposing the gap filling fluid to a plasma, e.g., oxygen plasma. In some embodiments, the conversion step comprises exposing the gap filling fluid to radicals, such as oxygen radicals.

In some embodiments, the method comprises a plurality of super cycles, in which case a super cycle comprises the step of at least partially filling the gap with a gap filling fluid, and the step of exposing the substrate to a transformation reactant.

In some embodiments, the gap filling fluid is formed in more than one reaction chamber.

Methods as described herein can comprise filling a gap by first forming a gap filling fluid in a first reaction chamber, and then converting the gap filling fluid to form a transformed material in a second reaction chamber. Thus, further described herein is a method for filling a gap. The method comprises providing a substrate. The substrate comprises the gap. The method further comprises providing a system comprising a gap filling fluid reaction chamber and a transformation reaction chamber. The method comprises executing one or more super cycles, for example, a plurality of super cycles. A super cycle comprises moving the substrate into the gap filling fluid reaction chamber. A super cycle further comprises forming a gap filling fluid in the gap filling fluid reaction chamber. Accordingly, the gap is at least partially filled with a gap filling fluid. It shall be understood that the gap filling fluid comprises a metal. A super cycle further comprises moving the substrate into the transformation reaction chamber. A super cycle further comprises exposing the substrate to a transformation treatment in the transformation reaction chamber. Thus, at least a part of the gap filling fluid is converted into a transformed material.

In some embodiments, a method as described herein comprises forming a gap filling fluid. Suitably, forming a gap filling fluid can comprise forming a gap filling fluid from a vapor phase precursor and a vapor phase reactant, such as a metal precursor and halogen precursor. Forming the gap filling fluid can comprise a plasma enhanced chemical vapor deposition process, or a thermal chemical vapor deposition process. Forming a gap filling fluid can comprise pulsed gas flow, continuous gas flow, or a regime in which some gasses are pulsed and others are flown continuously.

In some embodiments, forming a gap filling fluid comprises generating a plasma in the reaction chamber. A plasma may be generated continuously, or a plasma may be generated intermittently, i.e., in pulses. Thus, in some embodiments, a plasma is continuously generated in the reaction chamber, the reactant is continuously provided to the reaction chamber, and the precursor is provided to the reaction chamber in a plurality of precursor pulses. Alternatively, and in some embodiments, a plasma is generated in the reaction chamber intermittently, i.e., in pulses, the reactant is provided continuously in the reaction chamber, and the precursor is continuously provided to the reaction chamber. Alternatively, and in some embodiments, a plasma is not generated while forming a gap filling fluid, i.e., the gap filling fluid can be formed thermally.

In some embodiments, the metal precursor comprises an element that is selected from W, Ge, Sb, Te, Nb, Ta, V, Ti, Zr, Hf, Rh, Fe, Cr, Mo, Au, Pt, Ag, Ni, Cu, Co, Zn, Al, In, Sn, or Bi. In some embodiments, the precursor can comprise more than one metal, more than one metalloid, or at least one metal and at least one metalloid, in some embodiments. In some embodiments, the metal precursor comprises an element that is selected from V, Mo, Ti or Al. In some embodiments, the metal precursor comprises Al.

In some embodiments, the metal precursor comprises a ligand that, in turn, comprises a hydrocarbon.

In some embodiments, the precursor comprises at least one alkyl ligand, such as C1 to C4 alkyl, such as methyl, ethyl, propyl, or butyl. In some embodiments, the precursor comprises at least one alkoxide ligand, such as C2 to C4 alkoxide, such as ethoxide, propoxide, isopropoxide, or n-butoxide.

In some embodiments, forming a gap filling fluid comprises providing a halogen precursor into the reaction chamber in vapor phase. In some embodiment the halogen precursor is selected from the list consisting of halohydrocarbons, dihalogens, hydrogen halides, ammonium halides, and halosilanes. In some embodiments the hydrocarbon is a C2 to C4 alkene, such as ethylene, propylene, 1-butene, 2-butene or isobutene. In some embodiments, the hydrocarbon is an C1 to C4 alkyl, such as methyl, ethyl, propyl or butyl. In some embodiments, the hydrocarbon is an aryl, such as phenyl, naphthyl, tolyl or xylyl. In some embodiments, the hydrocarbon is an acyl. In some embodiments, the halogen comprises iodine, bromine, chlorine or fluorine.

In some embodiments, the halogen precursor is selected from the group consisting of semi-metal halides, sulfonic acids, sulfonates, antimony salts, halo-halogens, nitro-halides, oxyhalides, heteroleptic-boron halides, sulfenyl halides, selenenyl halides, substituted pentafluoro sulfanyls, substituted sulfur trifluoride, organo-sulfuryl halides and halo-succinimides. In some embodiments, the halogen precursor is selected from the group consisting of 2,2-difluoro-1,3-dimethylimidazolidine (DFI), perfluorodecanoic acid (PFDA), fluorosulfuric acid (HSO₃F), antimony pentachloride (SbCls), diethylaminosulfur trifluoride (DAST), peroxydicarbonic difluoride (C₂F₂O₄), and bromine trifluoride (BrF₃). In some embodiments, the halogen precursor is selected from the group consisting of a-fluoroalkylamines. In some embodiments, the a-fluoroamine comprises a compound containing at least one carbon atom that is bonded to both a nitrogen atom and a fluorine atom. In some embodiments, the a-fluoroamine has a formula of R₂NCF₂R′, where the R groups are independently any C1 to C6 hydrocarbon, and the R′ group is any one of the following: a C1-C6 hydrocarbon, a partially fluorinated C1-C6 hydrocarbon, a perfluoroalkyl group, a perfluoroaryl group, or an —NR₂ group. In some embodiments, the R or R′ groups are cyclic. In some embodiments, the cyclic R or R′ groups incorporate the “NCF₂” fragment of the a-fluoroamine. In some embodiments, the a-fluoroamine is 1,1,2,2,-tetrafluoroethyl-N,N-dimethylamine. In some embodiments, the a-fluoroamine is, 2,2-difluoro-1,3-dimethylimidazolidine. In some embodiments, the a-fluoroamine is N,N-diethyl-1,1,2,3,3,3-hexafluoro-1-propanamine. In some embodiments, the a-fluoroamine is 2-chloro-N,N-diethyl-1,1,2-trifluoroethanamine.

In some embodiments, the halogen precursor is selected from the group consisting of sulfur chlorides, phosphorous chlorides, acyl chlorides, n-chlorosuccimide and t-butyl hypochlorite. In some embodiments, the halogen precursor is selected from the group consisting of oxalyl chloride, acetyl chloride, thionyl chloride, sulfuryl chloride, alkyl sulfonyl chloride, disulfur dichloride and sulfur dichloride. In some embodiments, the halogen precursor is selected from the group consisting of phosphorous trichloride, phosphorous pentachloride, phosphorous oxychloride, dialkylphosphinic chloride, diarlphosphinic chloride, alkylphosphonic dichloride, arylphosphonic dichloride, n-chlorosuccimide, alkyl hypochlorite and tert-butyl hypochlorite.

In some embodiments the halogen precursor is selected from the group consisting of 1,1-dibromoalkanes, 1,2-dibromoalkanes, 1,1-diiodoalkanes, 1,2-diiodoalkanes, bromobenzene, iodobenzene, chlorobromide, chloroiodide, bromoiodide, oxalyl bromide, oxalyl iodide, silicon tetrabromide, silicon tetraiodide, dibromosilane, diiodosilane, tionyl bromide, tionyl iodide, tin bromide, tin iodide, aluminum bromide, aluminum iodide, titanium bromide, titanium iodide, phosphorous tribromide, phosphorous pentabromide, phosphorous oxybromide, phosphorous oxyiodide, N-bromosuccimide, N-iodosuccimide, tert-butyl hypobromite, ammonium bromide, ammonium iodide, pyrium bromide and pyridinum iodide.

In some embodiments, the halogen precursor is selected from the group consisting of a vicinal diiodoalkane of the formula RR′XCCR″R″X where X is iodine and where R and R′ and R″ and R″ are independently any C1 to C10 alkyl group, including branched or cyclic variants, or is an aryl group comprising 6-10 carbon atoms.

In some embodiments, the halogen precursor is selected from the group consisting of n-iodosuccinimide, 1,3-diiodo-5,5-dimethylhydantoin, N-iodosaccharin, diiodosilane, iodotrimethylsilane, tetramethylammonium iodide, tetrabutylammonium iodide, pyridinium iodide, pyrazinium iodide, pyrrolidinium iodide, acetyl iodide, 2,2-Dimethylpropanoyl iodide, benzoyl iodide, boron triiodide, diphosphorus tetraiodide and phosphorous triiodide.

A transformation treatment may be carried out after all gap filling fluid has been formed, or gap filling fluid formation steps and transformation treatments can be carried out multiple times in an alternating fashion. Thus, in some embodiments, a method as described herein comprises a plurality of super cycles. A super cycle comprises a step of exposing the substrate to a precursor and to a reactant, and the step of exposing the substrate to a transformation treatment.

A transformation treatment may, in some embodiments, be carried out in the same reaction chamber as the reaction chamber in which the gap filling fluid is formed. Alternatively, and in some embodiments, the gap filling fluid may be formed in a first reaction chamber, and the transformation treatment may be carried out in a second reaction chamber. The first and second reaction chambers may be part of a cluster tool comprising 2 or more, e.g., 2, 4, 8, 16, or 32, reaction chambers.

In some embodiments, the substrate is exposed to the transformation treatment for a duration of at least 0.1 s to at most 1000 s, or of at least 0.2 s to at most 500 s, or of at least 0.5 s to at most 200 s, or of at least 1.0 s to at most 100 s, or of at least 2 s to at most 50 s, or of at least 5 s to at most 20 s.

The transformation treatment can, in some embodiments, be carried out once after the gap has been filled, or it can be carried out multiple times, i.e., gap filling steps and transformation steps can be carried out alternatingly and cyclically in order to fill a gap with a transformed material. Thus, in some embodiments, a method as described herein comprises a plurality of super cycles. A super cycle comprises a step of at least partially filling a gap comprised in a substrate with a gap filling fluid and a step of exposing the substrate to a transformation treatment. For example, a method as described herein can comprise from at least 2 to at most 5, or from at least 5 to at most 10, or from at least 10 to at most 20, or from at least 20 to at most 50, or from at least 50 to at most 100 super cycles.

In some embodiments, a super cycle can directly follow a previous super cycle, or subsequent super cycles can be separated by an inter super cycle purge. A super cycle comprises forming a gap filling fluid and a transformation treatment. In some embodiments, the step of forming the gap filling fluid and the transformation treatment are executed directly after each other. Alternatively, a purge can be executed between a step of forming a gap filling fluid and a transformation treatment, before a step of forming a gap filling fluid, and/or between a transformation treatment and a subsequent step of forming a gap filling fluid.

The total number of super cycles comprised in a method as described herein depends, inter alia, on the total layer thickness that is desired. In some embodiments, the method comprises from at least 1 super cycle to at most 100 super cycles, or from at least 2 super cycles to at most 80 super cycles, or from at least 3 super cycles to at most 70 super cycles, or from at least 4 super cycles to at most 60 super cycles, or from at least 5 super cycles to at most 50 super cycles, or from at least 10 super cycles to at most 40 super cycles, or from at least 20 super cycles to at most 30 super cycles. In some embodiments, the method comprises at most 100 super cycles, or at most 90 super cycles, or at most 80 super cycles, or at most 70 super cycles, or at most 60 super cycles, or at most 50 super cycles, or at most 40 super cycles, or at most 30 super cycles, or at most 20 super cycles, or at most 10 super cycles, or at most 5 super cycles, or at most 4 super cycles, or at most 3 super cycles, or at most 2 super cycles, or a single super cycle.

A transformation treatment comprises exposing a substrate to a transformation reactant.

In some embodiments, the transformation treatment comprises exposing the substrate to a thermal anneal. Suitable anneals are known in the Art as such, and include spike anneals, rapid thermal anneals (RTA), and soak anneals. A thermal anneal can suitably be performed in a cyclical manner, e.g. after a deposition step in a super cycle. Additionally or alternatively, an anneal can be performed as a post-deposition treatment.

In some embodiments, the substrate is maintained at a temperature of at least −25° C. to at most 600° C., or at a temperature of at least 0° C. to at most 400° C., or at a temperature of at least 0° C. to at most 200° C., or at a temperature of at least 25° C. to at most 150° C., or at a temperature of at least 50° C. to at most 100° C. during at least one of forming a gap filling fluid and during the transformation treatment. It shall be understood that a suitable process temperature can be selected based on the vapor pressure of the gap filling fluid as a function of temperature. Suitable temperatures are those at which a gap filling fluid is in a liquid state, at least temporarily, during formation or after it has formed.

In some embodiments, and while the gap filling fluid is transformed into a transformed material, the substrate is maintained at a temperature of less than 800° C., or of at least −25° C. to at most 800° C., or of at least 0° C. to at most 700° C., or of at least 25° C. to at most 600° C., or of at least 50° C. to at most 400° C., or of at least 75° C. to at most 200° C., or of at least 100° C. to at most 150° C. In some embodiments, the temperature at which the substrate is maintained while the gap filling fluid is formed equals the temperature at which the substrate is maintained while the gap filling fluid is transformed into a transformed material.

In some embodiments, the presently described methods are carried out at a pressure of less than 760 Torr or of at least 0.2 Torr to at most 760 Torr, of at least 1 Torr to at most 100 Torr, or of at least 1 Torr to at most 10 Torr. In some embodiments, the metal precursor is deposited at a pressure of at most 10.0 Torr, or at a pressure of at most 5.0 Torr, or at a pressure of at most 3.0 Torr, or at a pressure of at most 2.0 Torr, or at a pressure of at most 1.0 Torr, or at a pressure of at most 0.1 Torr, or at a pressure of at least 0.2 Torr to at most 5 Torr, or at a pressure of at least 0.5 Torr to at most 2.0 Torr.

In some embodiments, the metal or metalloid comprised in the gap filling fluid comprises an element selected from the group consisting of W, Ge, Sb, Te, Nb, Ta, V, Ti, Zr, Hf, Rh, Fe, Cr, Mo, Au, Pt, Ag, Ni, Cu, Co, Zn, Al, In, Sn, and Bi. In some embodiments, the gap filling fluid further comprises a halogen. Suitable halogens include F, Cl, Br, and I.

In some embodiments, the metal precursor is selected from the group consisting of W(CO)(3-hexyne)₃, W(N^{t}Bu)₂ (NMe₂)₂, W₂ (NMe₂)₆, W(N^{t}Bu)₂ (ⁱPrAMD)₂, WH₂ (ⁱPrCp)₂, GeEt₂H₂, GeMe₂H₂, Ge(OEt)₄, Ge(OMe)₄, Sb(NMe₂)₃, Sb(OEt)₃, Et₂Te, Te(SiMe₃)₂, Te(OEt)₄, Te(SiEt₃)₂, Nb(N^{t}Bu) (NEt₂)₃, Nb(N^{t}Bu) (NEtMe)₃, Nb(OEt)₅, Ta(NEt)(NEt₂)₃, Ta(NEt₂)₅, Ta(NMe₂)₅, Ta(OEt)₅, V(NEt₂)₄, V(NEtMe)₄, VO(OiPr)₃, VO(OⁱPr)₃, Ti(NEt₂)₄, Ti(NEtMe)₄, Ti(NMe₂)₄, Ti(OiPr)₄, Ti(OMe)₄, Ti(OEt)₄, Ti(O^{t}Bu)₄, Zr(NEtMe)₄, Zr(O^{t}Bu)₄, Zr(NEt₂)₄, Zr(NMe₂)₄, Zr(OⁱPr)₄, Fe₂(^{t}BuO)₆, Mo(EtBen)₂, Mo(NMe₂)₄, Au(PMe₃)Me₃, Pt(CpMe)Me₃, Ag(O₂C^{t}Bu)(PEt₃), Cu(O₂C^{t}Bu)₂, CuCp(PEt₃), Co(CpEt)₂, Co(CpMe)₂, ZnEt₂, ZnMe(OⁱPr), ZnMe₂, AlMe₃, Al(OⁱPr)₃, Al(NEt₂)₃, Al(NiPr₂)₃, Al(NMe₂)₃, Al(OEt)₃, Al(OⁿPr)₃, Al(O^{s}Bu)₃, AlMe₂OⁱPr, AlEt₃, Al(Bu)₃, Al₂(NMe₂)₆, In(EtCp), InMe₃, InEt₃, InEtMe₂, Sn(NMe₂)₄, Sn(N SiMe₃)₂)₂, Sn(NEtMe)₄, Sn(O^{t}Bu)₄, SnMe₄, SnEt₄, Bi(NMe₂)₃, Bi(NMeEt)₃, Bi(O^{t}Bu)₃ and BiMe₃.

In some embodiments, the metal precursor is selected from the group consisting of AlMe₃, Al(OⁱPr)₃, Al(NEt₂)₃, Al(NⁱPr₂)₃, Al(NMe₂)₃, Al(OEt)₃, Al(OⁿPr)₃, Al(O^{S}Bu)₃, AlMe₂OⁱPr, AlEt₃, Al(ⁱBu)₃, Al₂(NMe₂)₆, Ti(NEt₂)₄, Ti(NEtMe)₄, Ti(NMe₂)₄, Ti(OⁱPr)₄, Ti(OMe)₄, Ti(OEt)₄, Ti(O^{t}Bu)₄, V(NEt₂)₄, V(NEtMe)₄, VO(OⁱPr)₃, VO(OⁿPr)₃, Mo(EtBen)₂ and Mo(NMe₂)₄.

In some embodiments, the precursor can comprise aluminum (Al). In such embodiments, the reactant can suitably comprise chlorine or iodine. Accordingly, a gap filling fluid comprising at least one of AlCl₃ and AlI₃ can be formed.

In some embodiments, the precursor can comprise molybdenum (Mo). In such embodiments, the reactant can suitably comprise chlorine, bromine, or iodine. Accordingly, a gap filling fluid comprising at least one of Mo₆Cl₁₂, MoCl₄, MoI₃, or MoBr₃ can be formed.

In some embodiments, the precursor can comprise titanium (Ti). In such embodiments, the reactant can suitably comprise fluorine. Accordingly, a gap filling fluid comprising TiF₄ can be formed.

In some embodiments, the precursor can comprise vanadium (V). In such embodiments, the reactant can suitably comprise one of fluorine or bromine. Accordingly, a gap filling fluid comprising at least one of VF₄, VF₅, or VBr₃ can be formed.

Further described herein is a system. The system comprises a reaction chamber and a precursor gas source. The precursor gas source comprises a precursor. The precursor can comprise a metal precursor. The system further comprises a deposition reactant gas source that comprises a deposition reactant. The system can be used for allowing the deposition reactant and the metalloid precursor to react, thereby forming a gap filling fluid.

The system further comprises a transformation reactant gas source. The transformation reactant gas source comprises a transformation reactant. Additionally or alternatively, the system can comprise one or more gas lines that are or can be arranged to provide the system with a transformation reactant. The system further comprises a controller. The controller is configured to control gas flow into the reaction chamber to carry out a method as described herein.

In some embodiments, the system comprises two distinct, i.e., separate, reaction chambers: a first reaction chamber and a second reaction chamber. The first reaction chamber is constructed and arranged for forming a gap filling fluid on the substrate. The second reaction chamber is constructed and arranged for converting the gap filling fluid into a transformed material. In some embodiments, the first reaction chamber is maintained at a first reaction chamber temperature, and the second reaction chamber is maintained at a second reaction chamber temperature. In some embodiments, the first reaction chamber temperature is lower than the second reaction chamber temperature, for example from at least 10° C. lower to at most 100° C. lower. In some embodiments, the first reaction chamber temperature is higher than the second reaction chamber temperature, for example, from at least 10° C. higher to at most 100° C. higher. In some embodiments, the first reaction chamber temperature is equal to the second reaction chamber temperature, e.g., within a margin of 10° C., 20° C., 30° C., or 40° C.

In some embodiments, a method as described herein can be carried out in a system comprising two reaction chambers. Thus, further described herein is a method for filling a gap. The method comprises providing a substrate. The substrate comprises the gap. The method further comprises providing a system that comprises a first reaction chamber and a second reaction chamber. The method further comprises providing a precursor to the first reaction chamber. The method further comprises providing a reactant to the second reaction chamber. The method further comprises executing a plurality of deposition cycles. A deposition cycle comprises moving the substrate to the first reaction chamber, and moving the substrate to the second reaction chamber. It shall be understood that at least one of the precursor and the reactant comprise a metal, and at least one of the precursor and the reactant comprise a halogen. Thus, the precursor and the reactant are allowed to form a gap filling fluid, and the gap is at least partially filled with the gap filling fluid. It shall be understood that the gap filling fluid comprises the metal. In some embodiments, the gap filling fluid further comprises the halogen.

In accordance with yet additional embodiments of the disclosure, a device or portion thereof can be formed using a method and/or a structure as described herein. The device can include a substrate, one or more insulating layers, one or more metallic layers, and one or more semiconducting layers. The device further comprises a gap filled using a method as disclosed herein.

The illustrations presented herein are not meant to be actual views of any particular material, structure, or device, but are merely idealized representations that are used to describe embodiments of the disclosure.

The particular implementations shown and described are illustrative of the invention and its best mode and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and subcombinations of the various processes, systems, and configurations, and other features, functions, acts, and/or properties disclosed herein, as well as any and all equivalents thereof.

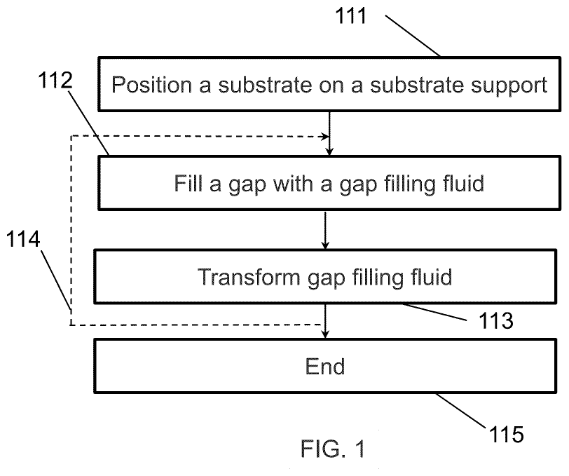

FIG. 1 shows a schematic representation of an embodiment of a method as described herein. The method can be used, for example, in order to form a gate, spacer, barrier or etch stop layer in a semiconductor device. However, unless otherwise noted, the presently described methods are not limited to such applications. The method comprises a step (111) of positioning a substrate on a substrate support. The substrate support is positioned in a reaction chamber. Suitable substrate supports include pedestals, susceptors, and the like. The method further comprises filling a gap comprised in the substrate (112) with a gap filling fluid. Suitable gap filling fluids and methods of forming them are described elsewhere herein. Optionally, the reaction chamber is then purged.

The method further comprises a step of transforming the gap filling fluid (113) to form a transformed material. In some embodiments, the step of transforming the gap filling fluid (113) to form a transformed material can be carried out in the same reaction chamber as the step of filling the gap comprised in the substrate (112). Alternatively, the step of transforming the gap filling fluid (113) to form a transformed material can be carried out in a different reaction chamber as the reaction chamber in which the step of filling the gap comprised in the substrate (112) is carried out.

Optionally, a purge is carried out after the step of transforming the gap filling fluid (113). When the step of transforming the gap filling fluid (113) to form a transformed material is carried out in the same reaction chamber as the step of filling the gap comprised in the substrate (112), then the purge can comprise temporarily stopping gas flow into the reaction chamber other than purge gas flow, such as flow of a noble gas. When the step of transforming the gap filling fluid (113) to form a transformed material is carried out in a different reaction chamber as the reaction chamber in which the step of filling the gap comprised in the substrate (112) is carried out, then transporting the substrate to the different reaction chamber itself can, in some embodiments, constitute a purge.

In one embodiment, the step of transforming the gap filling fluid (113) comprises a thermal transformation process that comprises exposing the substrate to a transformation reactant in a thermal way, that is without simultaneously exposing the substrate to an active species, e.g., a plasma-generated active species. In one embodiment, the step of transforming the gap filling fluid (113) comprises a plasma transformation process that comprises exposing the substrate to a plasma transformation reactant, that is simultaneously exposing the substrate to an active species, e.g. a plasma-generated active species. Optionally, the method of FIG. 1 comprises a plurality of super cycles (114) in which the steps of filling the gap with the gap filling fluid (112) and transforming the gap filling fluid (113) are repeated one or more times. After a pre-determined amount of transformed material has been formed on the substrate, the method of FIG. 1 ends (115).

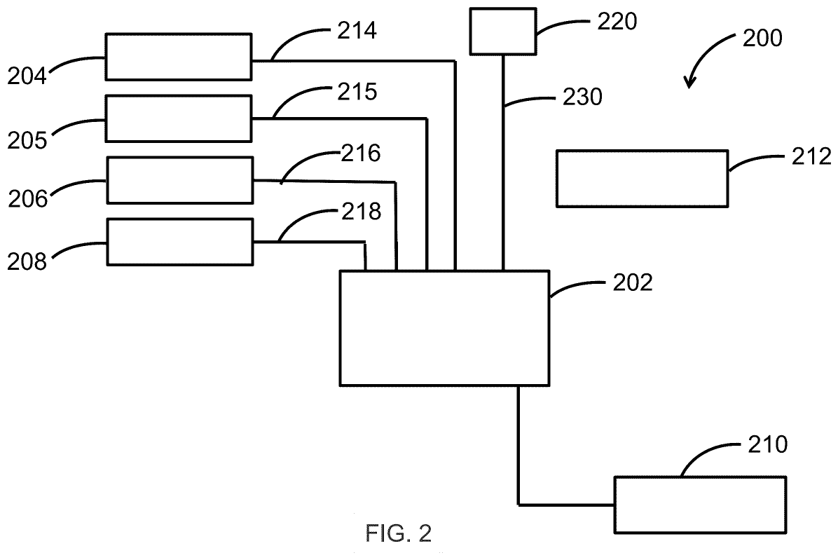

FIG. 2 illustrates a system (200) in accordance with yet additional exemplary embodiments of the disclosure. The system (200) can be used to perform a method as described herein and/or form a structure or device portion, e.g., in an integrated circuit, as described herein.

In the illustrated example, the system (200) includes one or more reaction chambers (202), a metal precursor gas source (204), a halogen precursor gas source (206), a purge gas source (208), an exhaust (210), and a controller (212).

The reaction chamber (202) can include any suitable reaction chamber, such as an ALD or CVD reaction chamber.

The precursor gas source (204) can include a vessel and one or more precursors as described herein-alone or mixed with one or more carrier (e.g., noble) gases. The halogen precursor gas source (206) can include a vessel and one or more reactants as described herein-alone or mixed with one or more carrier gases. The purge gas source (208) can include one or more inert gases as described herein. Although illustrated with four gas sources (204-208), the system (200) can include any suitable number of gas sources. The gas sources (204-208) can be coupled to reaction chamber (202) via lines (214-218), which can each include flow controllers, valves, heaters, and the like. The exhaust (210) can include one or more vacuum pumps.

The system (200) of FIG. 2 comprises, as illustrated, an optional remote plasma source (220) that is operationally coupled to the reaction chamber (202). It shall be understood that in some embodiments (not illustrated), the remote plasma source can be omitted. The inclusion of a remote plasma source (220) can be advantageous for forming a gap filling fluid, in some embodiments. Suitable remote plasma sources (220) as such are known in the Art, and comprise inductively coupled plasma sources, microwave plasma sources, and capacitive plasma sources. A remote plasma source can be positioned adjacent to the reaction chamber, or the remote plasma source can be positioned at a certain distance from the reaction chamber, e.g. at a distance of at least 1.0 m to at most 10.0 m. When the remote plasma source (220) is positioned at a certain distance from the reaction chamber (202), the remote plasma source (220) can be operationally connected to the reaction chamber (202) via an active species duct (230). The active species duct can comprise a pipe. Optionally, the pipe can contain one or more mesh plates. The mesh plates can at least partially block some reactive species such as ions and electromagnetic radiation while letting other reactive species, e.g., radicals, pass.

In some embodiments, other plasmas can be used in addition or as an alternative to the remote plasma, in some embodiments. Suitable additional or alternative plasmas include indirect plasmas and direct plasmas. Thus, and in some embodiments, the reaction chamber comprises a showerhead injector, a substrate support, and a direct plasma source (none of which are shown). In exemplary modes of operation, an RF bias can be applied to the showerhead injector by the direct plasma source, and the substrate support can be grounded. Thus, a substrate can be efficiently exposed to a direct plasma which can be useful, for example, when forming a gap filling fluid, or when exposing a transformed material to a post-transformation plasma treatment.

The controller (212) includes electronic circuitry and software to selectively operate valves, manifolds, heaters, pumps and other components included in the system (200). Such circuitry and components operate to introduce precursors, reactants, and purge gases from the respective sources (204-208). The controller (212) can control timing of gas pulse sequences, temperature of the substrate and/or reaction chamber, pressure within the reaction chamber, and various other operations to provide proper operation of the system (200). The controller (212) can include control software to electrically or pneumatically control valves to control flow of precursors, reactants and purge gases into and out of the reaction chamber (202). The controller (212) can include modules such as a software or hardware component, e.g., a FPGA or ASIC, which performs certain tasks. A module can advantageously be configured to reside on the addressable storage medium of the control system and be configured to execute one or more processes.

Other configurations of the system (200) are possible, including different numbers and kinds of precursor and reactant sources and purge gas sources. Further, it will be appreciated that there are many arrangements of valves, conduits, precursor sources, and purge gas sources that may be used to accomplish the goal of selectively feeding gases into the reaction chamber (202). Further, as a schematic representation of a system, many components have been omitted for simplicity of illustration, and such components may include, for example, various valves, manifolds, purifiers, heaters, containers, vents, and/or bypasses.

During operation of the system (200), substrates, such as semiconductor wafers (not illustrated), are transferred from, e.g., a substrate handling system to reaction chamber (202). Once such substrate(s) are transferred to reaction chamber (202), one or more gases from the gas sources (204-208), such as precursors, reactants, carrier gases, and/or purge gases, are introduced into the reaction chamber (202).

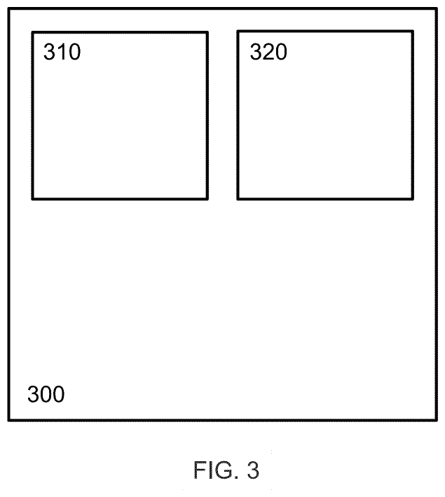

FIG. 3 shows another embodiment of a system (300) as described herein in a stylized way. The system (300) of FIG. 3 is similar to that of FIG. 2. It comprises two distinct reaction chambers: a first reaction chamber (310) and a second reaction chamber (320). The first reaction chamber (310) is arranged for at least partially filling a gap with a gap filling fluid. The second reaction chamber (320) is arranged for transforming the gap filling fluid into a transformed material.

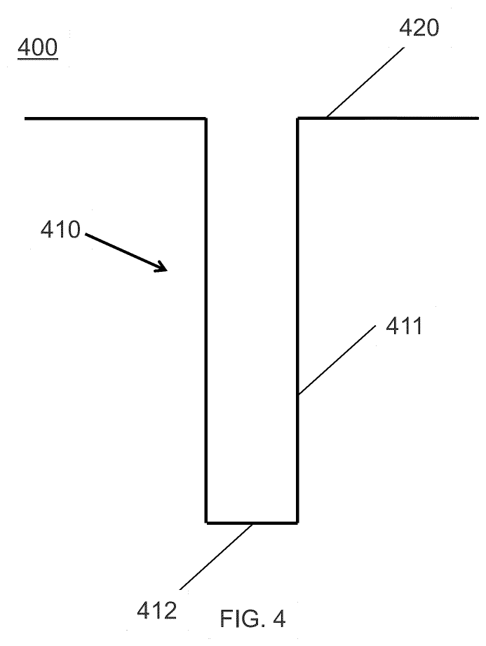

FIG. 4 shows a schematic representation of a substrate (500) comprising a gap (410). The gap (410) comprises a sidewall (411) and a distal end (412). The substrate further comprises a proximal surface (420). In some embodiments, the sidewall (411) and the distal end (412) comprise the same material. In some embodiments, at least one of the sidewall (411) and the distal end comprise a dielectric, such as a silicon containing dielectric such as silicon oxide, silicon nitride, silicon carbide, and mixtures thereof. In some embodiments, the dielectric comprises hydrogen. In some embodiments, at least one of the sidewall (411) and the distal end (412) comprise a metal such as a transition metal, a post transition metal, and a rare earth metal. In some embodiments, the metal comprises Cu, Co, W, Ru, Mo, Al, or an alloy thereof. In some embodiments, at least one of the sidewall (411) and the distal end (412)

In some embodiments, the sidewall (411) and the distal end (412) have an identical, or a substantially identical, composition. In some embodiments, the sidewall (411) and the distal end (412) have a different composition. In some embodiments, the sidewall and the distal end (412) comprise a dielectric. In some embodiments, the sidewall (411) and the distal end (412) comprise a metal. In some embodiments, the sidewall (411) comprises a metal and the distal end (412) comprises a dielectric. In some embodiments, the sidewall (411) comprises a dielectric and the distal end comprises a metal.

In some embodiments, the proximal surface (420) has the same composition as the sidewall (411). In some embodiments, the proximal surface (420) has a different composition than the sidewall (411). In some embodiments, the proximal surface (420) has a different composition than the distal end (412). In some embodiments, the proximal surface (420) has the same composition as the distal end (412).

In some embodiments, the proximal surface (420), the sidewall (411), and the distal end (412) comprise the same material. In some embodiments, the proximal surface (420), the sidewall (411), and the distal end (412) comprise a dielectric. In some embodiments, the proximal surface (420), the sidewall (411), and the distal end (412) comprise a metal. In some embodiments, the proximal surface (420), the sidewall (411), and the distal end (412) comprise a semiconductor.

1. A method for filling a gap, the method comprising:
providing a substrate to a reaction chamber, the substrate comprising the gap;
providing a metal precursor into the reaction chamber in vapor phase;
providing a halogen precursor into the reaction chamber in vapor phase, thereby forming a gap filling fluid; and
exposing the gap filling fluid to a transformation reactant, thereby converting at least part of the gap filling fluid into a transformed material.

2. The method according to claim 1, wherein the metal precursor comprises a metal and a hydrocarbon ligand.

3. The method according to claim 2, wherein the hydrocarbon ligand comprises an alkyl group or an alkoxide group.

4. The method according to claim 2, wherein the hydrocarbon ligand is selected from the group consisting of ethyl, methyl, ethoxide, propoxide, isopropoxide, n-butoxide, and combinations thereof.

5. The method according to claim 1, wherein the metal precursor comprises an element selected from the group consisting of W, Ge, Sb, Te, Nb, Ta, V, Ti, Zr, Rh, Fe, Cr, Mo, Au, Pt, Ag, Ni, Cu, Co, Zn, Al, In, Sn, and Bi.

6. The method according to claim 5, wherein the metal precursor comprises an element selected from the group consisting of V, Mo, Ti, and Al.

7. The method according to claim 6, wherein the metal precursor comprises Al.

8. The method according to claim 1, wherein the metal precursor is selected from the group consisting of W(CO)(3-hexyne)₃, W(N^{t}Bu)₂ (NMe₂)₂, W₂ (NMe₂)₆, W(N^{t}Bu)₂ (ⁱPrAMD)₂, WH₂ (ⁱPrCp)₂, GeEt₂H₂, GeMe₂H₂, Ge(OEt)₄, Ge(OMe)₄, Sb(NMe₂)₃, Sb(OEt)₃, Et₂Te, Te(SiMe₃)₂, Te(OEt)₄, Te(SiEt₃)₂, Nb(N^{t}Bu) (NEt₂)₃, Nb(N^{t}Bu) (NEtMe)₃, Nb(OEt)₅, Ta(NEt)(NEt₂)₃, Ta(NEt₂)₅, Ta(NMe₂)₅, Ta(OEt)₅, V(NEt₂)₄, V(NEtMe)₄, VO(OiPr)₃, VO(OⁱPr)₃, Ti(NEt₂)₄, Ti(NEtMe)₄, Ti(NMe₂)₄, Ti(OiPr)₄, Ti(OMe)₄, Ti(OEt)₄, Ti(O^{t}Bu)₄, Zr(NEtMe)₄, Zr(O^{t}Bu)₄, Zr(NEt₂)₄, Zr(NMe₂)₄, Zr(OⁱPr)₄, Fe₂(^{t}BuO)₆, Mo(EtBen)₂, Mo(NMe₂)₄, Au(PMe₃)Me₃, Pt(CpMe)Me₃, Ag(O₂C^{t}Bu)(PEt₃), Cu(O₂C^{t}Bu)₂, CuCp(PEt₃), Co(CpEt)₂, Co(CpMe)₂, ZnEt₂, ZnMe(OⁱPr), ZnMe₂, AlMe₃, Al(OⁱPr)₃, Al(NEt₂)₃, Al(NiPr₂)₃, Al(NMe₂)₃, Al(OEt)₃, Al(OⁿPr)₃, Al(O^{s}Bu)₃, AlMe₂OⁱPr, AlEt₃, Al(Bu)₃, Al₂(NMe₂)₆, In(EtCp), InMe₃, InEt₃, InEtMe₂, Sn(NMe₂)₄, Sn(N SiMe₃)₂)₂, Sn(NEtMe)₄, Sn(O^{t}Bu)₄, SnMe₄, SnEt₄, Bi(NMe₂)₃, Bi(NMeEt)₃, Bi(O^{t}Bu)₃ and BiMe₃.

9. The method according to claim 1, wherein the metal precursor is selected from the group consisting of AlMe₃, Al(OⁱPr)₃, Al(NEt₂)₃, Al(NⁱPr₂)₃, Al(NMe₂)₃, Al(OEt)₃, Al(OⁿPr)₃, Al(O^{S}Bu)₃, AlMe₂OⁱPr, AlEt₃, Al(ⁱBu)₃, Al₂(NMe₂)₆, Ti(NEt₂)₄, Ti(NEtMe)₄, Ti(NMe₂)₄, Ti(OⁱPr)₄, Ti(OMe)₄, Ti(OEt)₄, Ti(O^{t}Bu)₄, V(NEt₂)₄, V(NEtMe)₄, VO(OⁱPr)₃, VO(OⁿPr)₃, Mo(EtBen)₂ and Mo(NMe₂)₄.

10. The method according to claim 1, wherein the halogen precursor is selected from the group consisting of halohydrocarbons, dihalogens, hydrogen halides, ammonium halides, and halosilanes.

11. The method according to claim 10, wherein the halogen precursor is a halohydrocarbon, and wherein the halohydrocarbon is selected from the list consisting of haloalkenes, haloalkanes, aryl halides and acyl halides.

12. The method according to claim 1, wherein the gap filling fluid comprises a metal halide.

13. The method according to claim 1, wherein the transformation reactant comprises an oxidizing reactant.

14. The method according to claim 13, wherein the oxidizing reactant is selected from the group consisting of ozone, water, steam, vacuum ultraviolet (VUV)-ozone, and oxygen plasma.

15. A method for filling a gap, the method comprising:
providing a substrate, the substrate comprising the gap;
providing a system comprising a gap filling fluid reaction chamber and a transformation reaction chamber;
executing a plurality of super cycles, a super cycle comprising:
moving the substrate into the gap filling fluid reaction chamber;
forming a gap filling fluid in the gap filling fluid reaction chamber, thereby at least partially filling the gap with the gap filling fluid;
moving the substrate into the transformation reaction chamber; and
subjecting the substrate to a transformation treatment in the transformation reaction chamber, thereby converting at least a part of the gap filling fluid into a transformed material.

16. The method according to claim 15, comprising executing a plurality of super cycles, a super cycle comprising at least partially filling the gap with a gap filling fluid, and the step of subjecting the substrate to a transformation reactant.

17. A system comprising:
a reaction chamber;
a first precursor gas source comprising a metal precursor;
a second precursor gas source comprising a halogen precursor; and
a controller, wherein the controller is configured to control gas flow into the reaction chamber to form a layer on a substrate by a method according to claim 1.
